(19) United States
(12) Patent Application Publication
(10) Pub. No.: US 2010/0280784 A1
(43) Pub. Date: Nov. 4, 2010

(54) Method for monitoring the quality of a control circuit in a power plant

(76) Inventors: Alexander Dressler, Bad Friedrichshall (DE); Klaus Wendelberger, St. Leon-Rot (DE)

Correspondence Address: SIEMENS CORPORATION;INTELLECTUAL PROPERTY DEPARTMENT, 170 WOOD AVENUE SOUTH, ISELIN, NJ, 08830, US

(21) Appl. No.: 12/740,130

(22) PCT Filed: Oct. 29, 2008
(86) PCT No.: PCT/EP2008/064678

§ 371 Date: Jul. 14, 2010

(30) Foreign Application Priority Data
Oct. 29, 2007 (DE) 10 2007 051 547.4

(51) Int. Cl. G01R 27/28; G06F 19/00

(52) U.S. Cl. 702/117

(57) ABSTRACT

A method of monitoring quality of a control circuit in a power plant is provided. The quality of the control circuit is continuously assessed by determining characteristic quantities describing the quality by applying a plurality of testing methods suitable for describing dynamic properties of the control circuit to current operating data originating from the instrumentation and control equipment of the power plant, and by evaluating the characteristic quantities. Further, a system and a computer readable medium are provided.

### CROSS REFERENCE TO RELATED APPLICATIONS

This application is the US National Stage of International Application No. PCT/EP2008/064678 filed. Oct. 29, 2008, and claims the benefit thereof. The International Application claims the benefits of German Patent Application No. 10 2007 051 547.4 DE filed Oct. 29, 2007. All of the applications are incorporated by reference herein in their entirety.

### FIELD OF INVENTION

The invention relates to a method for monitoring the quality of a control circuit in a power plant. The invention additionally relates to a system for monitoring the quality of a control circuit in a power plant, instrumentation and control equipment for a power plant and a computer program for monitoring the quality of a control circuit in a power plant.

### SUMMARY OF INVENTION

In power plants, i.e. industrial facilities for producing electricity and in some cases also thermal power, complex process engineering processes take place. For example, it is necessary not only to run a power plant at different operating points, but also to move quickly and efficiently between them. Correct operation of the power plant is ensured by a large number of control circuits.

To increase cost-effectiveness, modern control methods are increasingly used, the manipulated variables of which are the setpoints of underlying control systems. Said modern control methods require that the control circuits function exactly as when they were put into service.

The quality of a control circuit in a power plant, hereinafter also referred to as “control quality”, changes during operation due to changes in the process equipment, e.g. fouling, wearout of the mechanical actuators (valves, motors, etc.) among other things. Such changes in the control quality can adversely affect the plan's operation and cost-effectiveness.

The deterioration is detected by monitoring the control quality, and the controller can be adapted to the new conditions. For this purpose, the control quality is determined from time to time from archived operating data with the aid of external computers. Complex mathematical methods are used here, the results of which have to be interpreted by experts. In some existing systems, small disturbances must be applied to the process in order to determine the control quality. One disadvantage of this is that a deterioration in the control quality can only be ascertained when a monitoring procedure is initiated by a higher-order process.

An object of the present invention is to provide early detection of deterioration in the quality of a control circuit in a power plant.

This object is achieved by a method as claimed in the independent claim. The advantages and embodiments explained below in the context of the method also apply mutatis mutandis to the system according to the invention.

It is inventively provided that the control quality of a control circuit is continuously assessed. For such continuous control circuit quality monitoring, characteristic quantities describing the control quality are determined. These characteristic quantities are also evaluated. To determine the characteristic quantities, testing methods are applied to current operating data originating from the power plant's instrumentation and control equipment. The testing methods are methods that are suitable for describing dynamic properties of a control circuit.

In contrast to the prior art, the control quality is not therefore monitored at intervals using archive data, but permanently and enduringly, “online” so to speak, and using current operating data. Any deterioration of the control quality is therefore immediately apparent. The controller can be corrected or other action taken without delay.

A central idea of the invention is therefore to provide systematic controller assessment which rates both steady-state and dynamic behavior of a control circuit on the basis of characteristic quantities. The major advantage of this is the immediacy. The inventive monitoring of control circuit quality gives the plant operator instant feedback about the control quality. Critical control circuits can therefore be filtered out during operation. Unlike in conventional systems, there is no need to wait until enough relevant data has been collected and processed.

The control circuits of a power plant, which are in most cases adjusted once during the startup phase and only rarely re-adjusted thereafter, are inventively evaluated systematically and can therefore also be regularly improved. This reduces the plant operator's workload. The efficiency of the power plant is increased and the operating costs reduced, as each badly adjusted control circuit causes additional mass flows which cannot be converted into output and therefore reduce the cost-effectiveness of the plant.

Since with the aid of the invention it can be quickly ascertained which control circuit is functioning inadequately, no unnecessary time is taken up looking for it. Conversely, more time is available for optimizing the control circuit.

In general, control circuits change only very slowly over time. A deterioration in the control quality is therefore only detected relatively late by the plant operator. With the control quality monitoring system according to the invention, the rate of deterioration is irrelevant.

Of particular importance is the fact that the proposed uninterrupted control circuit quality monitoring can provide an overall view and assessment of all the control circuits of a power plant in a particularly simple manner. The control circuits of a power plant can therefore undergo a continuous improvement process.

The object is also achieved by a system for monitoring the quality of a control system in a power plant, having means to carry out the method described.

The object is also achieved by power plant instrumentation and control equipment in which such a system is incorporated. The integration ensures simple data and information flow within the power plant instrumentation and control equipment. This simplifies uninterrupted monitoring of the control quality and allows an immediate, possibly even automated response to control quality deteriorations, e.g. in the form of action initiated by the instrumentation and control equipment.

The object is also achieved by a computer program for monitoring the quality of a control circuit in a power plant, said computer program being characterized in that it has computer program instructions for continuous assessment of the control quality by determining characteristic quantities describing the control circuit by applying a number of testing methods suitable for describing dynamic properties of a control circuit to operating data originating from the power plant's instrumentation and control equipment and evaluating said characteristic quantities when the computer program is run on a computer, preferably a power plant instrumentation and control computer.

In other words, the inventive system preferably incorporated in the instrumentation and control equipment of the power plant is designed to carry out the described method for monitoring the quality of a control circuit in a power plant. Said system is preferably a data processing unit, designed to perform all the steps according to the method described here which are associated with the processing of data. The data processing unit preferably has a number of functional modules, each functional module being implemented to perform a particular function or number of particular functions according to the described method. In other words, the functional modules of the data processing unit are the means for executing the described method. Said functional modules can be hardware modules or software modules. In other words, insofar as it relates to the data processing unit, the invention can be realized either in the form of computer hardware or in the form of computer software or in a combination of hardware and software. Where the invention is realized in software, i.e. as a computer program product, all the functions described are implemented by computer program instructions when the computer program is run on a computer with a processor. Said computer program instructions are realized in per se known manner in any programming language and can be made available to the computer in any form, e.g. in the form of data packets transmitted over a computer network, or in the form of a computer program product stored on a diskette, a CD-ROM or other data media. In other words, the invention is preferably implemented in software as an integral component of an instrumentation and control computer.

Advantageous embodiments of the invention are set forth in the dependent claims.

The control circuit quality monitoring system according to the invention is designed not only to assess and monitor the control quality under steady-state conditions but also the dynamics of the control circuit. The dynamic behavior of a control circuit manifests itself in setpoint changes. It is not therefore necessary to register the characteristic quantities of the control circuit both under steady-state conditions and in the event of setpoint changes. A load change involves, on the one hand, a setpoint change of a large number of control circuits. On the other hand, the load change causes larger disturbances in the control circuits than during steady-state operation. For the control quality, a distinction must therefore be made between steady state and load change. In other words, to prevent the characteristic quantities from being incorrectly calculated due to transients, it must be precisely defined when a steady state obtains and when a load change is present. For this purpose, in one embodiment of the invention, power plant operation is subdivided into load profiles and the control quality is assessed separately in each case for said load profiles such that the characteristic quantities describe the control quality at constant load or at load changes. The load profiles will hereinafter also be referred to as “categories”.

To obtain the characteristic quantities, operating data from the instrumentation and control equipment of the power plant is used. Said operating data is advantageously used uncompressed and/or unprocessed so that there is no additional computational complexity.

The testing methods are preferably methods that are suitable not only for describing steady-state properties of the control circuit but also for describing dynamic properties of a control circuit. In addition, however, methods can also be used which are suitable solely for describing dynamic properties of a control circuit and not for describing steady-state properties, or else methods which are suitable solely for describing steady-state properties of a control circuit and not for describing dynamic properties.

To describe the dynamic properties of a control circuit, one or more of the following testing methods are preferably used: determining the integrated absolute control error (IAE), determining the moving average, determining the standard deviation, detecting the occurrence of wind-up, detecting oscillations. Here per se known mathematical methods are applied either in the usual way and/or such methods are extended in terms of continuous control circuit quality monitoring.

These methods used enable the characteristic quantities to be calculated in a comparatively simple manner. As the control circuit quality monitoring system is preferably installed in the instrumentation and control system of a power plant to monitor a large number of control circuits there, the necessary memory space and the required computing time must not be excessively large in order to guarantee the full functionality of the instrumentation and control system while at the same time performing the monitoring function.

The control circuit quality monitoring is designed such that comparatively few parameters must be set, as the time available to an engineer for adjusting a control circuit, especially a subsidiary control circuit, and monitoring it during the startup phase, is limited. This simplifies and speeds up the commissioning of the control circuit quality monitoring system.

The control circuit quality monitoring system fulfills the criterion of process independence. In other words, it operates for different processes, so that it can be applied to a plurality of control circuits within a power plant which differ in respect of the process to be controlled, actuators, measuring elements, etc.

Models mainly exist only for higher-order, more complex control systems. Lower-order controlled systems are often not modeled, as the benefit does not justify the expense. As the area of application of the control circuit monitoring according to the invention is lower-order control systems, it must be assumed that no models are available or are produced. The control circuit quality monitoring according to the invention therefore fulfills the criterion of model independence. For assessing the control quality, it is not absolutely necessary for a suitable model of the controlled system to be available.

In one embodiment of the invention, a two-part method sequence is provided. First, reference control qualities for load changes and steady state, i.e. a state without load changes, are determined in a learning phase. During said learning phase, an engineer or the like observes the control circuits. The control circuits must be defined as satisfactory by the engineer during the learning phase. If this is not the case, the control circuits must be re-adjusted and the learning phase is repeated. Then, in a monitoring phase, the thus determined reference control qualities are used as comparison values for assessing the continuously determined control quality. Preferably both the changes in the characteristic quantities and the overall quality are output as the result.

In another embodiment of the invention, when evaluating the characteristic quantities, an exceedance of permissible deviations is determined and a deterioration of the controlled variable is output as the number of characteristic quantities for which such an exceedance is present. For example, if five characteristic quantities are evaluated and a deterioration in control quality is determined because two of said five characteristic quantities have changed impermissibly, a signal is output which indicates a “2 out of 5” deterioration. This means that two out of five characteristic quantities have exceeded the permissible deviations. This information can be output in different ways, e.g. via a visual and/or audible display. In other words, the plant operator receives at all times easy-to-understand feedback about the state of the control circuits. This means that no expert is required to interpret the results.

If immediate “on-line” evaluation of control quality is not to take place, but further analysis is planned, the characteristic quantities are preferably additionally recorded in an archive and/or made available for more detailed analyses. Said archive can be implemented in the form of a data memory as an integral part of the instrumentation and control equipment of the power plant. However, in the light of limited computing and storage capacities of the instrumentation and control system, archiving or forwarding of the characteristic quantities to an external receiver, e.g. an archiving and/or analyzing computer outside the power plant instrumentation and control system, is provided.

To summarize, it can be stated that with the aid of the present invention it is possible, without additional hardware, to provide the user, in this case the plant operator, with direct information about the quality of the control circuits in the power plant. If a deterioration in control quality is ascertained, the control circuits affected can be analyzed. An expert, e.g. an engineer, can then change the controller setting or if necessary change the control strategy.

### BRIEF DESCRIPTION OF THE DRAWINGS

The invention will now be described with reference to exemplary embodiments which are explained in greater detail with the aid of the accompanying drawings. These are simplified, in some cases schematic illustrations in which:

FIG. 1 shows a power plant,

FIG. 2 shows an CODA loop,

FIG. 3 shows a learning phase,

FIG. 4 shows a monitoring phase,

FIG. 5 shows a control quality setpoint monitoring system,

FIG. 6 shows a single-loop control circuit,

FIG. 7 shows a controlled variable,

FIG. 8 shows a setpoint change,

FIG. 9 shows a noisy measurement signal of the controlled variable,

FIG. 10 shows a moving average of the measured variable,

FIG. 11 shows a signal waveform with moving average,

FIG. 12 shows an oscillation of the control error,

FIG. 13 shows an asymmetrical oscillation of the control error,

FIG. 14 shows a ramped setpoint change with noise,

FIG. 15 shows minima and maxima in the IAE response,

FIG. 16 shows an IAE time slice for a load change,

FIG. 17 shows an average of the controlled variable,

FIG. 18 shows a setpoint change with noise,

FIG. 19 shows a control error,

FIG. 20 shows minima and maxima of the standard deviation,

FIG. 21 shows a binary wind-up signal,

FIG. 22 shows a relative wind-up signal,

FIG. 23 shows an oscillation after setpoint change (4%/min),

FIG. 24 shows an oscillation after setpoint change (2%/min),

FIG. 25 shows an oscillation after setpoint change (−4%/min),

FIG. 26 shows an oscillation detection flowchart,

FIG. 27 shows oscillation detection (first method),

FIG. 28 shows oscillation detection (second method),

FIG. 29 shows an oscillation detection flowchart,

FIG. 30 shows a setpoint response,

FIG. 31 shows a setpoint and controlled variable response,

FIG. 32 shows an IAE response for a dynamic process,

FIG. 33 shows an IAE response for steady-state recording,

FIG. 34 shows a moving average of the control error,

FIG. 35 shows a standard deviation of the control error,

FIG. 36 shows a standard deviation of the controlled variable,

FIG. 37 shows a standard deviation of the manipulated variable,

FIG. 38 shows an IAE response,

FIG. 39 shows an IAE response,

FIG. 40 shows a moving average of the control error,

FIG. 41 shows a standard deviation of the control error,

FIG. 42 shows a standard deviation of the controlled variable,

FIG. 43 shows a standard deviation of the manipulated variable,

FIG. 44 shows a display possibility using colors.

### DETAILED DESCRIPTION OF INVENTION

Identical reference characters in the Figures described below correspond to elements of the same or comparable function.

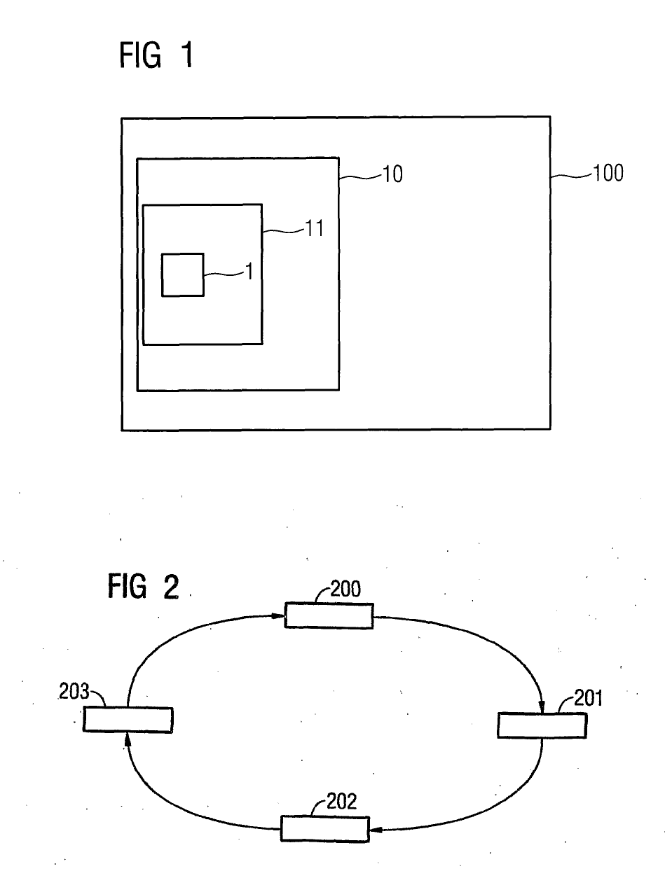

The control circuit quality monitoring system is used in the instrumentation and control equipment of a power plant, particularly in an SPPA T3000 instrumentation and control system. The instrumentation and control system acquires the measurements from the plant and controls the actuators. All the controls which are not directly implemented in the field are installed here. The control circuit quality monitoring system can therefore access all the relevant operating data. Said control circuit quality monitoring system is subject to the computing cycle in which calculations are performed in the instrumentation and control system (e.g. every 100 ms). FIG. 1 schematically illustrates a power plant 100 with an instrumentation and control system 10 which has a computer 11 on which control circuit quality monitoring according to the invention in the form of a computer program 1 is executed.

The control circuit quality monitoring system is used for continuous monitoring of the power plant. However, the control circuits not only have to be monitored. Unsatisfactory control circuits must be filtered out and analyzed. The cause of the inadequate control quality is determined by detailed analysis. To improve the control quality, countermeasures must be selected and implemented. The monitoring, analysis and the selection and implementation of countermeasures must take place continuously in order to maintain constant or improve the control quality and therefore also the efficiency of the control circuit. To ensure the continuity of this process, an overall strategy for controller assessment is necessary.

One possibility here is to use an OODA loop, see FIG. 2. The OODA loop consists of four elements: observation, orientation, decision and action. In the observation phase 200, data concerning the control circuit is collected. This data is analyzed and assessed in the orientation phase 201. Using the analysis, countermeasures can be selected in the decision phase 202. These are implemented in the action phase 203. With the control circuit quality monitoring system according to the invention, the observation 200 and orientation phases 201 are merged. The collecting of data and assessment of the control quality is performed “on-line” by the control circuit quality monitoring system. The more detailed analysis and the countermeasures are carried out by a control engineer. Conspicuous control circuits are pre-selected by the control quality monitoring system and provided with meaningful characteristic numbers. By registering the characteristic quantities it is additionally possible to specify precisely the change in the control quality following a control change.

The control circuit quality monitoring according to the invention is part of a bottom-up assessment. This means that the control circuits are assessed individually and therefore the plant is monitored from bottom to top. To determine the control quality, the characteristic quantities which rate the control quality under steady-state conditions and in the event of setpoint changes are determined using methods presented in detail below.

Said steady state is defined using a constant ε as follows:

$$\frac{d}{d t} \sum {\dot{m}}_{fuel} < ɛ for t \geq {T}_{s}$$

The characteristic numbers for the load change are calculated if the following condition is fulfilled:

$${ɛ}_{U} < \frac{d {P}_{setpo int}}{d t} < {ɛ}_{0} for t \geq {T}_{L}$$

and with the additional condition that a steady state has first been ascertained. The time constants Tₛ and T_{L} are multiples of the cumulative time constant Tₛᵤₘ of the controlled system observed.

Load changes that are too short to fulfill the abovementioned condition, or load changes that are too large, are placed in another category “Other”. This category is used only for orientation over a lengthy period and not for explicit assessment of the control quality.

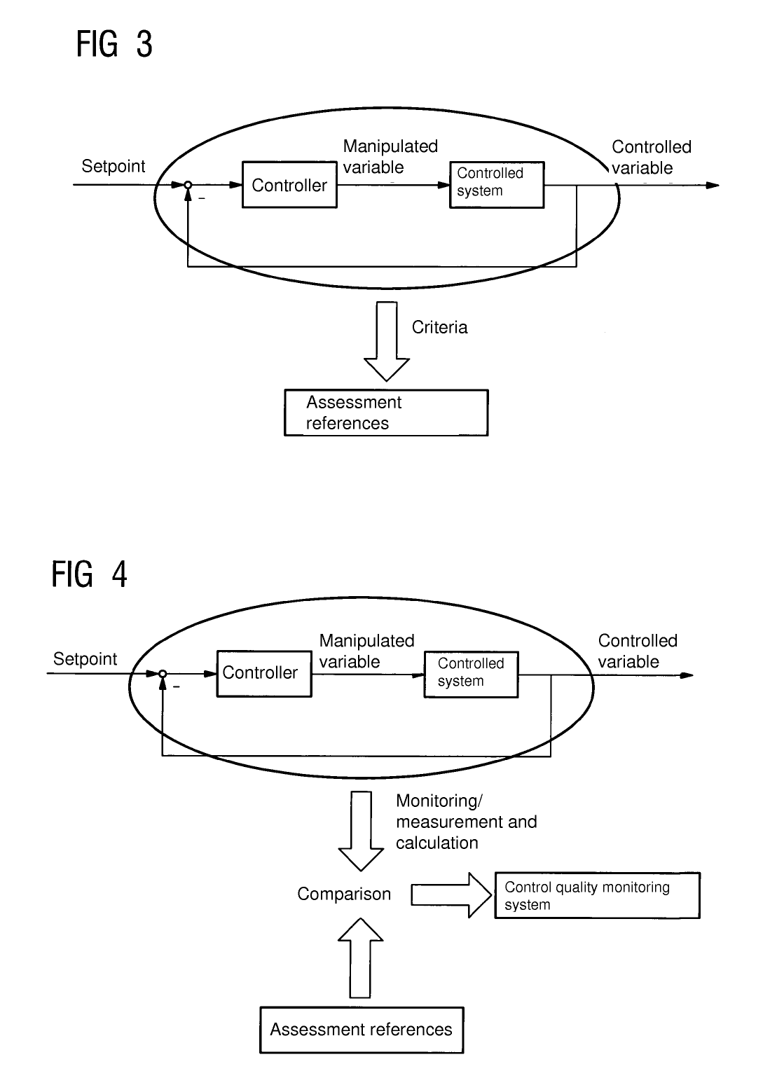

In order to determine a change in the control quality, a reference control quality is defined. The behavior of the control circuits must first be assessed as satisfactory by an expert, e.g. an engineer. Then, in a so-called learning phase, the control circuit quality monitoring system according to the invention registers the dynamic and static properties of the control circuit, see FIG. 3. These are used as reference for the monitoring. In the subsequent monitoring phase, the control circuit quality monitoring system continuously monitors the control circuit using the reference, see FIG. 4. Deviations occurring which exceed the predefined tolerances are indicated as a reduction in control quality.

The learning phase critically determines the subsequent monitoring phase. If the control circuit is not already satisfactorily adjusted, e.g. oscillations or wind-up frequently occur, only a worse control quality can be ascertained in the monitoring phase. If the control quality remains at a constant but poor level, the control circuit cannot be filtered out by the control circuit quality monitoring system.

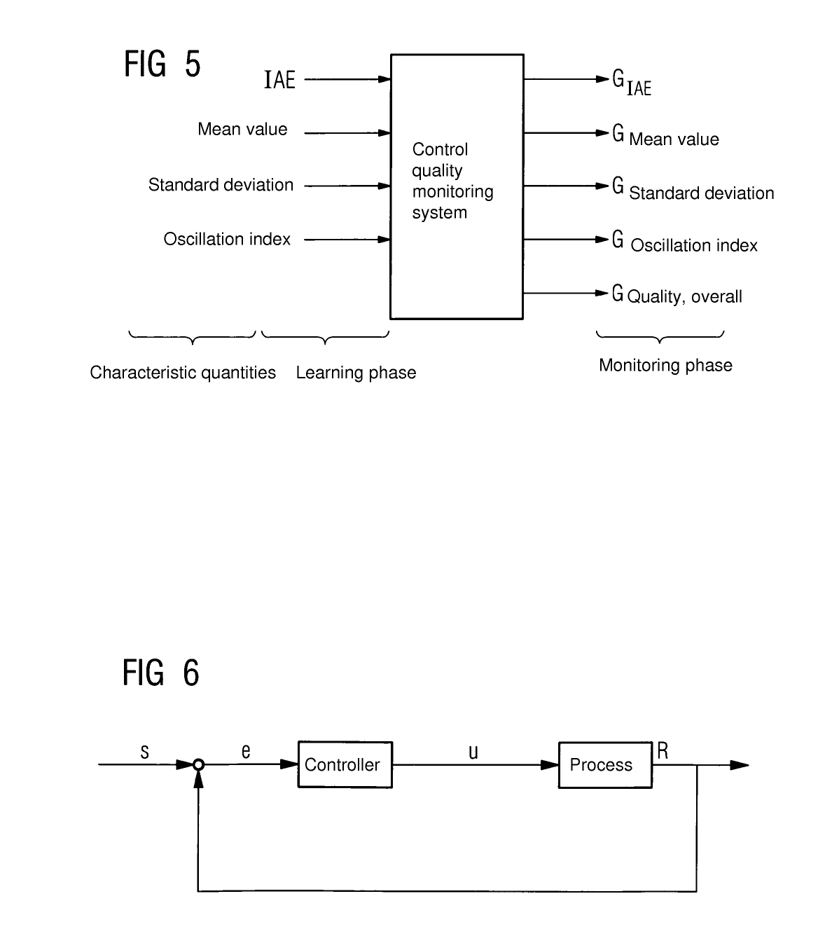

In the monitoring phase, the control quality is continuously determined, both the changes in the characteristic quantities and the overall quality being output, see FIG. 5.

Details of the measurement data or operating data flow within the instrumentation and control system of the power plant to the control circuit quality monitoring software implemented as a module of the instrumentation and control system as well as information concerning the interface programming, etc. are not specified, as they are familiar to the average person skilled in the art.

Before the mode of operation of the control circuit quality monitoring is illustrated on the basis of a test, the mathematical methods preferably used for determining the characteristic quantities will be described.

By way of example, a control circuit of a power plant as depicted in FIG. 6 will be assumed. The setpoints are denoted by S, the controlled variable by R, the manipulated variable by u and the control error by e. This single-loop control circuit serves as the basis for the following considerations and explanations of the methods.

The most important and meaningful variable for assessing the control quality is the control error e(t), i.e. the difference between setpoint S(t) and controlled variable R(t). Considering the control error only at certain points gives no information about the dynamic behavior of the control circuit. Therefore, the response of the integral absolute error (IAE) is considered.

$$IAE = {\int }_{0}^{T} \vert e ( t ) \vert d t$$

This method assesses the control error response linearly over the period of time considered (observation period) T and therefore indicates the dynamic properties of the control circuit.

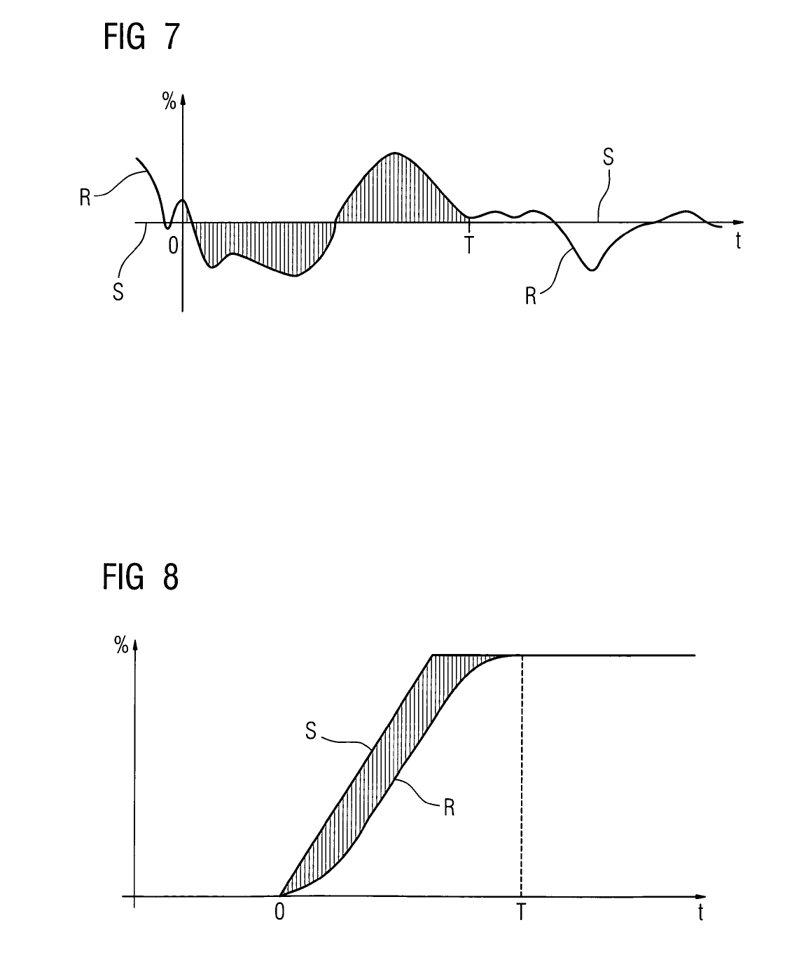

The properties of the control circuit in respect of disturbance correction are assessed by integration over time T under steady-state conditions. The better the controller corrects disturbances, the smaller the area between controlled variable R and setpoint S, see FIG. 7.

The dynamic behavior in the event of setpoint changes is assessed. If the control circuit is well able to follow the setpoint, the integral is small, see FIG. 8.

Measured signals are generally noisy to a lesser or greater extent. In order to increase the meaningfulness of the measurement signals and make e.g. trends clearer, it is necessary to determine the mean value of a signal. The mean value over time T is calculated as follows:

$$Meanvalue = \frac{1}{T} {\int }_{0}^{T} x ( t ) d t$$

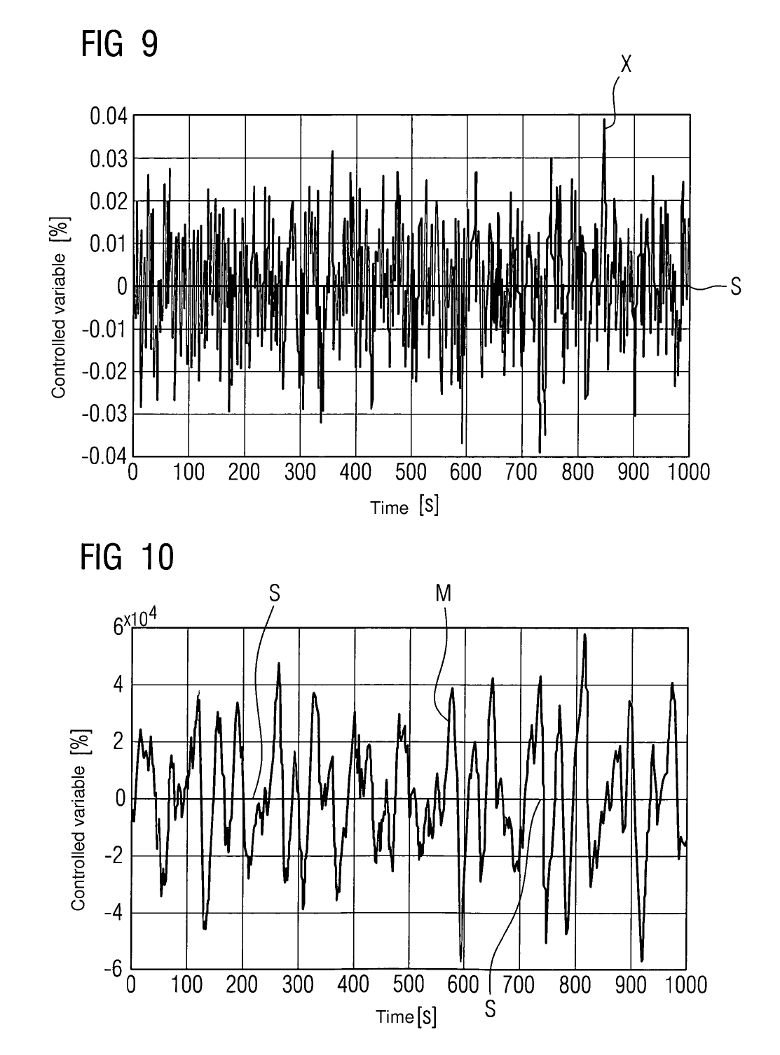

As shown in FIG. 9 and FIG. 10, the signal is smoothed and a sinusoidal oscillation is clearly evident. The amplitudes are also lower. The use of the moving average M is therefore important because only thus can a permanent control deviation be ascertained. In the case of a noisy signal X, it is not possible to measure the permanent control error. The signal is smoothed by the moving average M and the permanent control error becomes clear.

Not only the mean value of a signal is relevant for assessing the control quality, but also the deviation from the mean value. Said deviation from the mean is the standard deviation. The standard deviation is defined as the square root of the variance of the signal and therefore has the same unit as the measured values:

σₓ=\sqrt{Var(X)}

i.e.

σₓ={square root over (E((X−E(X))²))}

where σₓ is the standard deviation of the measured signal x(t) and E[ . . . ] the expected value of [ . . . ].

If the mean value of the controlled variable moves closely around the setpoint, for example, a large variance means that the control is nevertheless not functioning satisfactorily. A large variance means that disturbances are not adequately damped. The standard deviation is estimated for samples using the following equation:

$${s}_{x} = \sqrt{\frac{1}{N - 1} {\sum }_{i = 1}^{N} {( {x}_{i} - \overline{x} )}^{2}}$$

In other words, Sₓ represents the estimate for the standard deviation of x(t).

For cumulative samples (measured values) it is impractical to store all the measured values and calculate the standard deviation. The standard deviation is therefore estimated using the following equation:

$${s}_{x} = \sqrt{\frac{N {\sum }_{i = 1}^{N} {x}_{i}^{2} - {( {\sum }_{i = 1}^{N} {x}_{i} )}^{2}}{N ( N - 1 )}}$$

The mean value is defined as follows:

$$\overline{x} = {\sum }_{i = 1}^{N} \frac{{x}_{i}}{N}$$

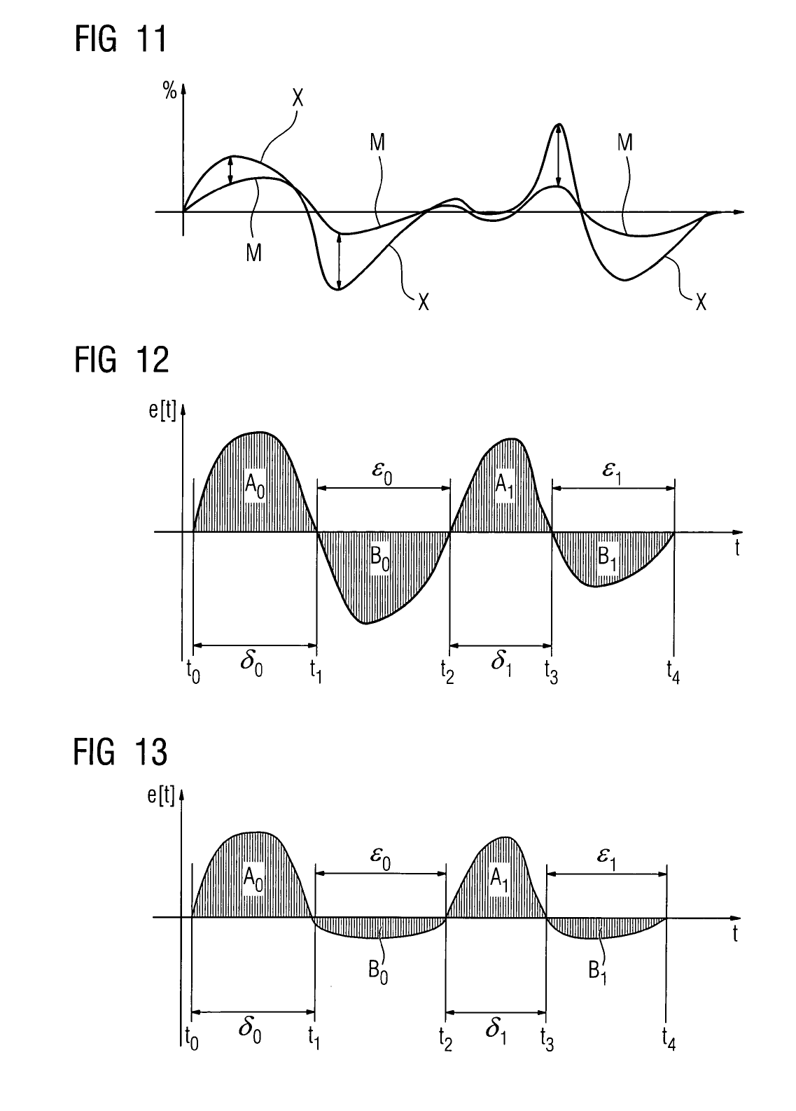

Disturbances in the control circuit force the controlled variable away from its setpoint. The object of the control is to bring it back. If the control is operating properly, the deviations are small, see FIG. 11 which shows a signal waveform X with a moving average M.

Another important characteristic quantity which indicates whether the control circuit is operating satisfactorily is the time period which occurs in the wind-up.

$${I}_{Wind \text{-} up} = \frac{{T}_{Wind \text{-} up}}{{T}_{Observe}}$$

Wind-up means that the actuator cannot adjust the manipulated variable to the value set by the controller. This may be the case when the actuator is at an end stop (e.g. completely open or completely closed) or when the actuator cannot be adjusted more quickly. The occurrence of wind-up means that the controller loses its control capability and disturbances can only be exacerbated or not corrected at all. It is therefore necessary to relate the time period with wind-up (T_{Wind-up}) to an observation time (T_{Observ}) in order to observe the control quality. Causes of wind-up include worn actuators or actuators which can only act monotonically on the controlled system, e.g. only inject water, and actuators which have been incorrectly designed and do not allow the required manipulated variables or rates of change.

Oscillations occur in control circuits if the control is not functioning satisfactorily. The causes of this are many and varied, e.g. high friction in the actuator or incorrect controller settings which result in oscillations. Oscillations in a control circuit can spread over the entire plant, thereby severely disturbing operation. It is therefore important that the control circuit quality monitoring system according to the invention can also detect oscillations in order to simplify subsequent cause analysis. In the case of plant-wide oscillations, it is important to filter out the control circuit causing the oscillation from all the oscillating control circuits.

Two methods for detecting oscillations in control circuits will now be presented. The first method compares the quotient of the absolute value of the control error (IAE) between two zero crossings

$${IAE}_{i} = {\int }_{{t}_{i}}^{{t}_{i + 1}} \vert e ( t ) \vert d t$$

and the time between the zero crossings, with a constant term:

$$\frac{{IAE}_{i}}{Δ {T}_{i}} \geq δ$$

If this holds true, the deviation between the zero crossings was part of an oscillation and not noise. An important element of this method is the constant 5. This determines whether or not a deviation of the control error is part of an oscillation. It is assumed that δ is the product of the root mean square σ and the constant ζ. A value for ζ has to be obtained by experience and experiment. For estimation of the constants this gives:

$$\frac{{IAE}_{i}}{Δ {T}_{i}} \geq σ \cdot ξ$$

where σ as the standard deviation of the control error and ζ is the quotient of maximum and standard deviation.

The second method for detecting oscillations in control circuits compares areas and time lags to detect oscillations. The absolute control error is integrated between the zero crossings, as in the case of the first method. The time between the zero crossings is likewise measured. If the areas (areas of the control deviations between the zero crossings) are on the same side of the control error and the associated times are similar, an oscillation is present. FIG. 12 shows a typical waveform, the associated areas and the measured times. If the areas A₀ and A₁, the times δ₀ and δ₁, the areas B₀ and B₁, and the times ε₀ and ε₁ are similar, an oscillation is detected.

One aspect of this method is that it can also be used to detect asymmetrical oscillations, as only the areas on the same side of the control error can ever be compared with one another. This is advantageous if, as shown in FIG. 13, the areas B₀ and B₁ are not immediately detected as part of an oscillation and e.g. the areas A₀ and A₁ are interpreted as two mutually independent disturbances.

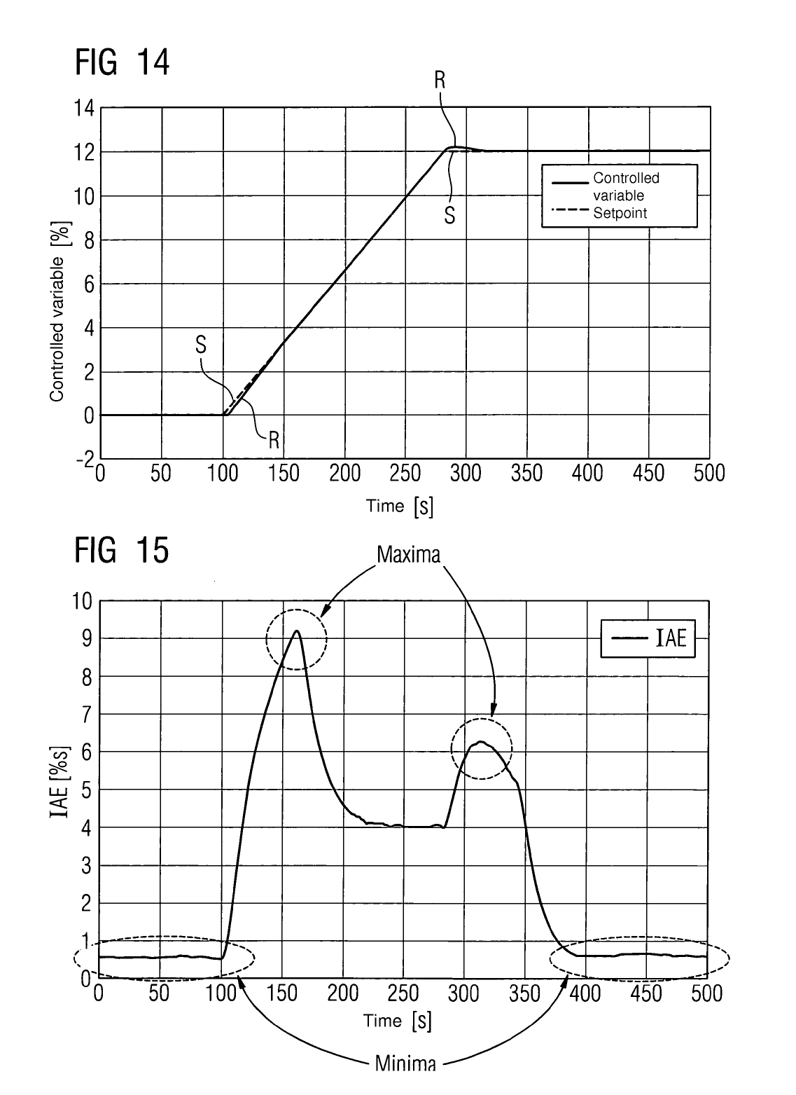

An example of control circuit quality monitoring will now be described. FIG. 14 shows a typical response of the controlled variable of a control circuit in the event of a ramped setpoint change. The associated waveform of the integral absolute error is shown in FIG. 15. It can be clearly seen that there are three minima.

Under steady-state conditions, only the noise determines the IAE response. During the setpoint change, there is one transition region, after which control error is virtually constant. During the transition region, maxima and minima occur in the IAE response, see FIG. 15. The minima describe the behavior of the control circuit under steady-state conditions.

In steady state, the IAE is determined only by the noise. Therefore a large time period must be integrated in order not to track the noise. If a large time period is selected, here T=6×T_{Sum}, the noise suppression is measured with IAE, see also FIG. 7.

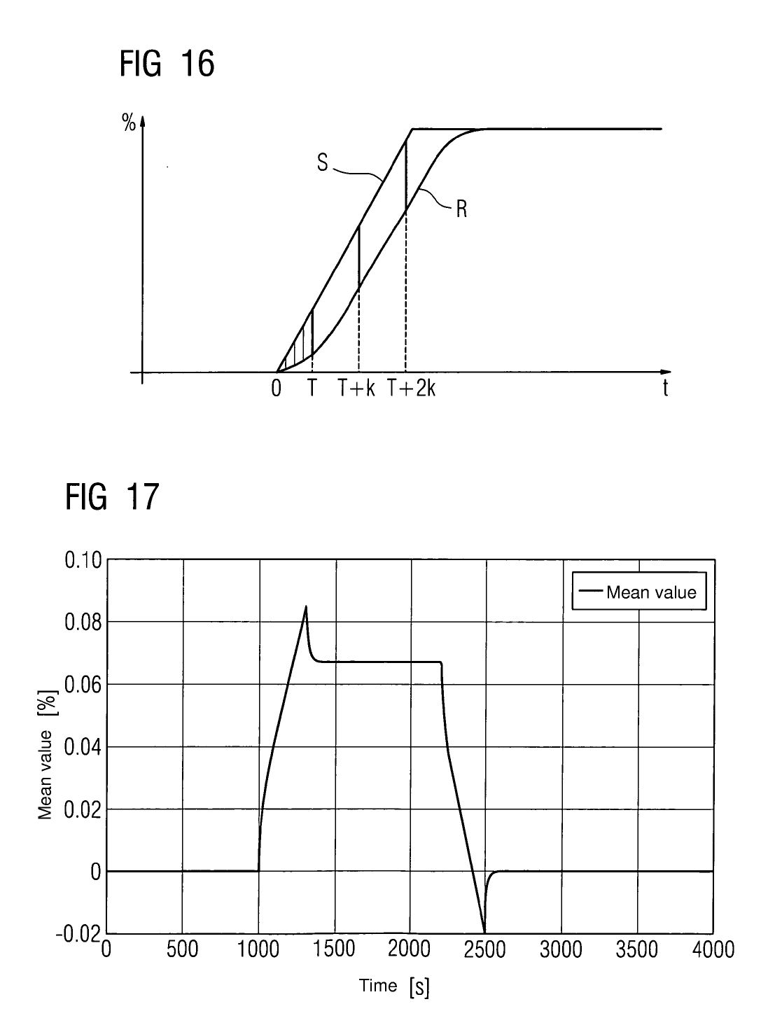

In the case of load changes, the maxima occurring during them indicate the dynamic properties. For identical load change, the maxima are approximately identical. If the control circuit becomes more sluggish, the maximum increases, as the control error also increases automatically compared to the reference due to the more sluggish control circuit. The inertia of the control circuit is therefore monitored with the recording of the maximum, see FIG. 16.

The mean value of the control error indicates how well the controlled variable is approximated to the setpoint by the control system. The minimum of the control error is therefore the characteristic number for a permanent control deviation. If the control error moves close to zero under steady-state conditions, there is no permanent control deviation, see FIG. 17.

The minimum permanent control deviation that has occurred after setpoint changes is stored in the learning phase. Excessively large deviations from this reference value indicate reduced control quality. This may be caused by, for example, constant disturbances or worn-out actuators.

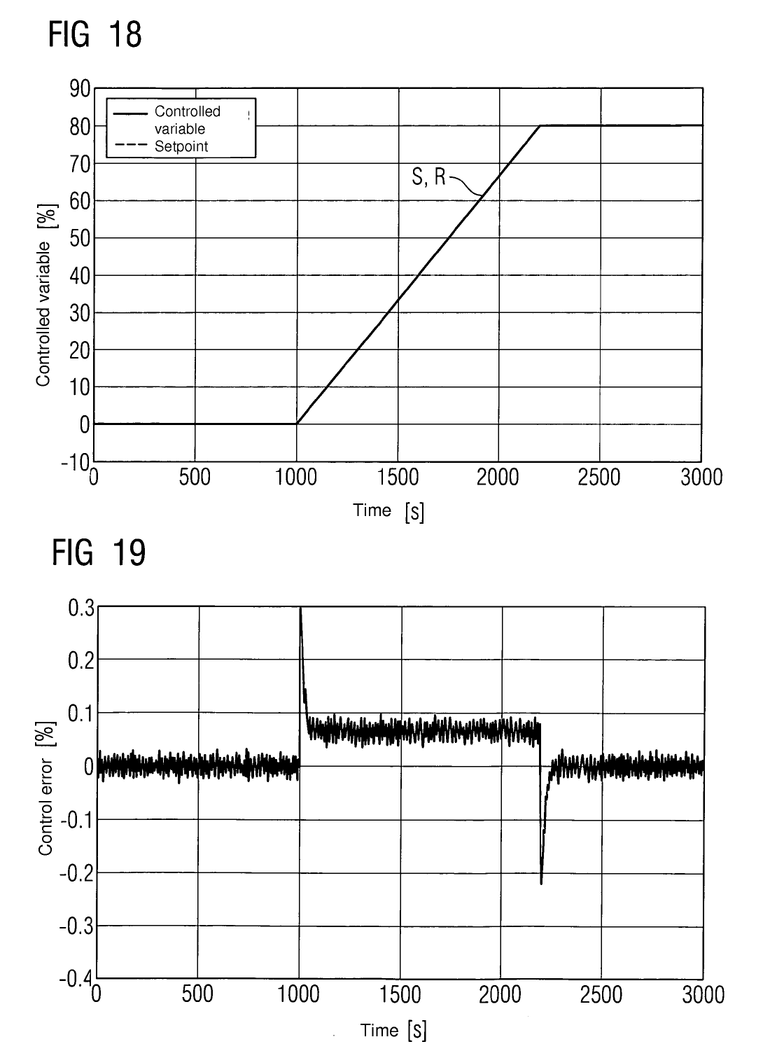

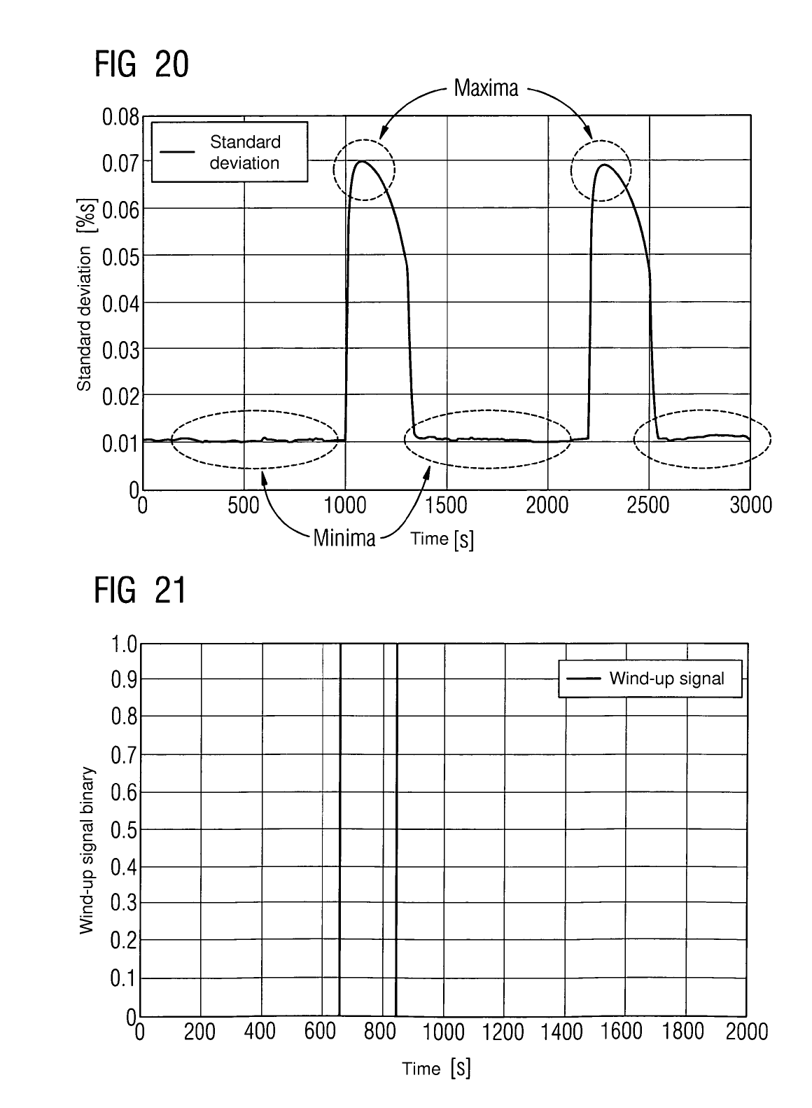

FIGS. 18 and 19 show a ramped setpoint change and the associated control error. The standard deviation associated with the control error is illustrated in FIG. 20. The minima of the standard deviation are produced solely by the noise and therefore indicate how quietly the process is being controlled.

In the event of a load change, the maxima are produced by the transition from steady state to setpoint change and back. If the maximum increases, disturbances during the setpoint change prevent a better control quality, cf. FIG. 20.

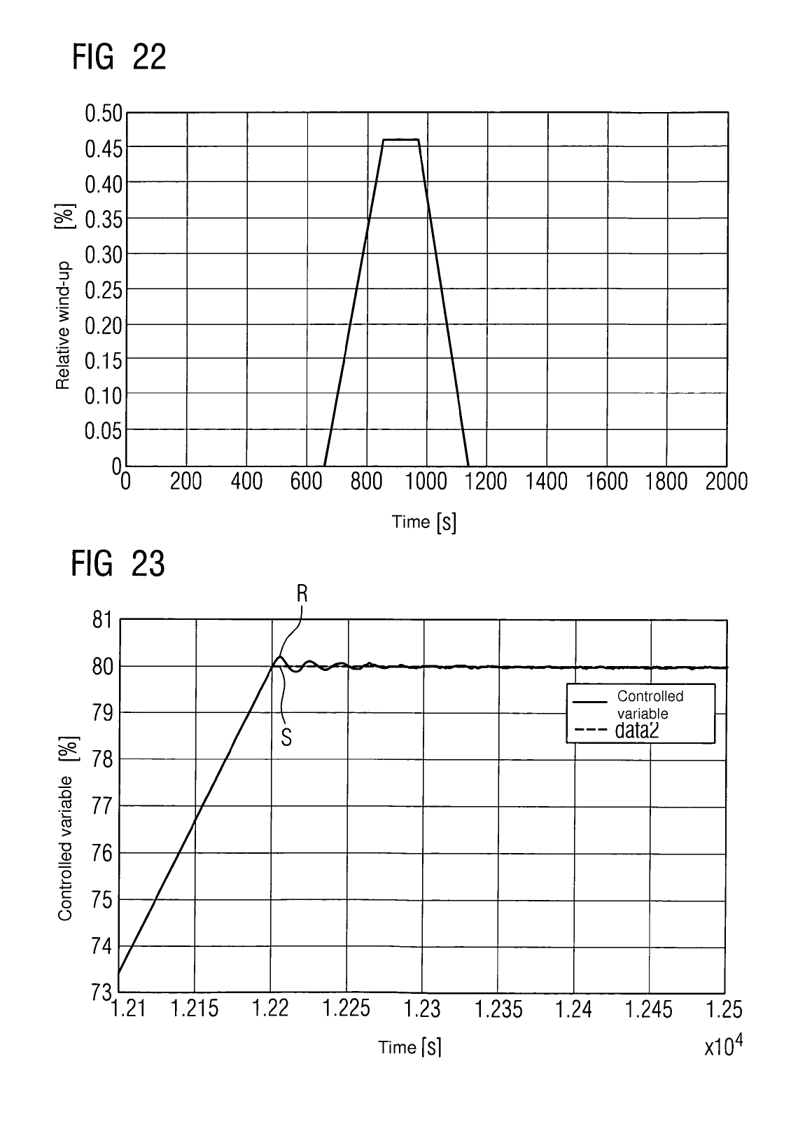

In order to determine the relative wind-up time, an observation period must be determined. Here too it is practical to assume the time period to be a multiple of the cumulative time constant, e.g. T=4×T_{Sum}. If wind-up occurs, see FIG. 21, a response as shown in FIG. 22 is produced. A ramped response is produced by the moving time window.

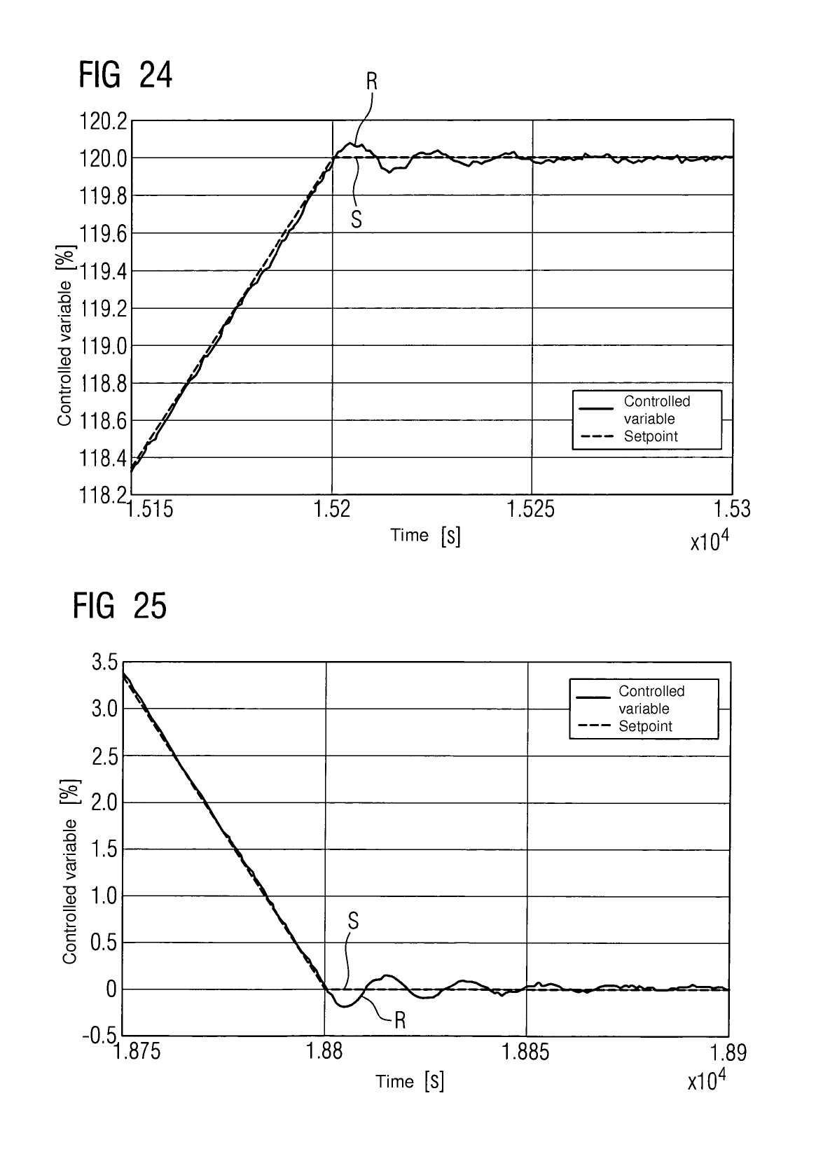

The FIGS. 23, 24 and 25 show the occurrence of oscillations after a setpoint change. How the two above methods detect these oscillation and which adaptations took place for using the methods for control circuit quality monitoring will now be described.

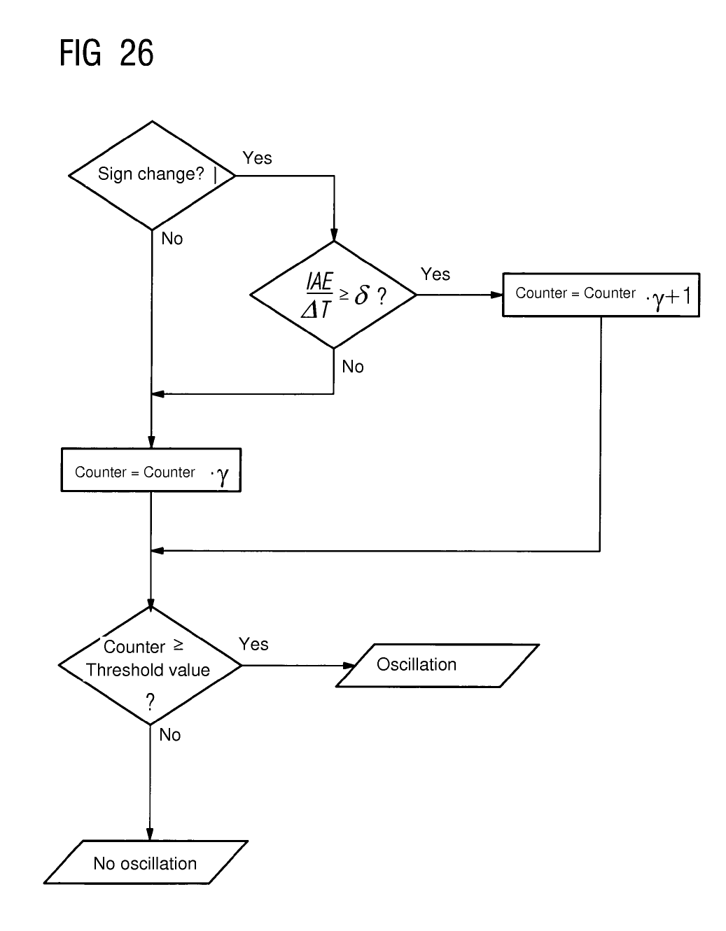

The adaptations of the first method to on-line detection are slight. The main elements are the introduction of a threshold value and the forgetting factor γ. These reduce erroneous detections due to noise. A flowchart for the adapted algorithm for on-line detection is shown in FIG. 26.

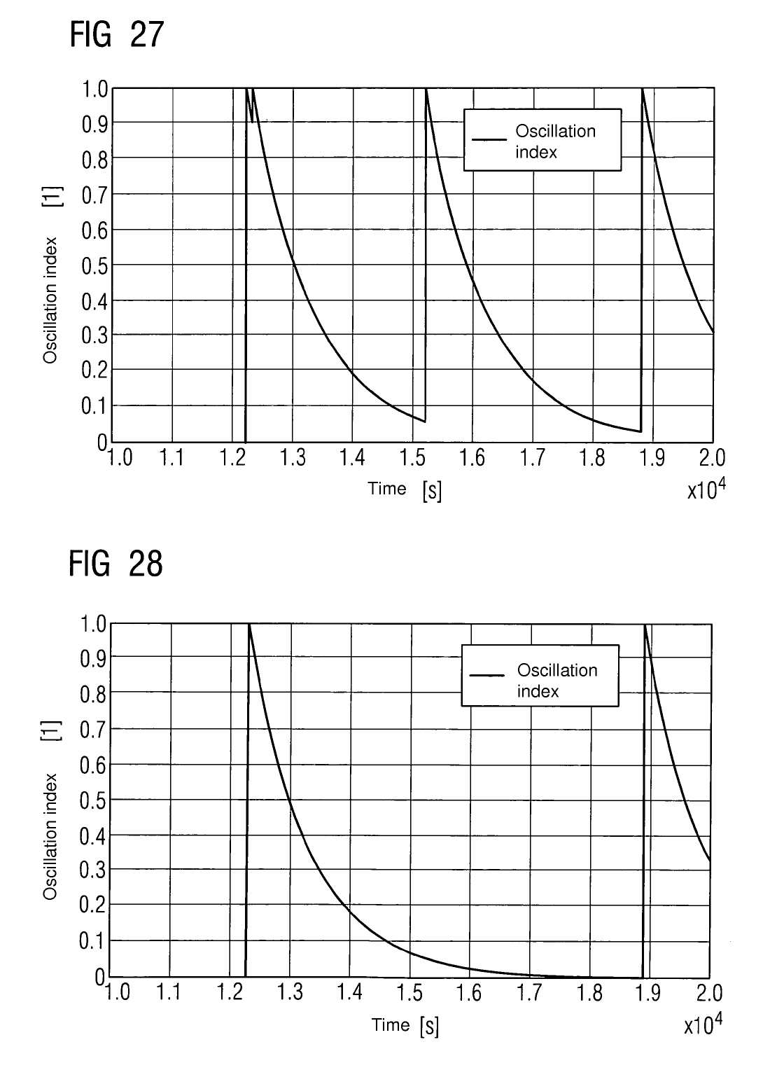

FIG. 27 shows oscillation detection according to the first method. The high sensitivity of this method is shown for the first oscillation occurring at t=12200s, see also FIG. 23. As only a small number of sub-cycles are necessary (depending on the threshold value), the oscillation index jumps to 1 twice within a short time and therefore indicates an oscillation.

In order to optimize the second method for detecting oscillations for on-line detection and avoid mistaking noise for oscillation, the conditions already described above are extended. The areas and times not only have to be similar, but the quotient of area Aᵢ and time δᵢ, or Bᵢ and εᵢ, must be greater than the root mean square (Luis) of the signal, see the two following equations:

$$α < \frac{{A}_{i + 1}}{{A}_{i}} < \frac{1}{α} ⋀ β < \frac{{δ}_{i + 1}}{{δ}_{i}} < \frac{1}{β} ⋀ \frac{{A}_{i}}{{δ}_{i}} > rms$$

$$α < \frac{{B}_{i + 1}}{{B}_{i}} < \frac{1}{α} ⋀ β < \frac{{ɛ}_{i + 1}}{{ɛ}_{i}} < \frac{1}{β} ⋀ \frac{{B}_{i}}{{ɛ}_{i}} > rms$$

Therefore, a deviation from the setpoint must be greater than the root mean square to be detected as part of an oscillation.

FIG. 28 shows the output of the oscillation detection according to the second method. Clearly apparent is the lesser “rigor” of this method, e.g. the oscillation after 15150 seconds is not detected.

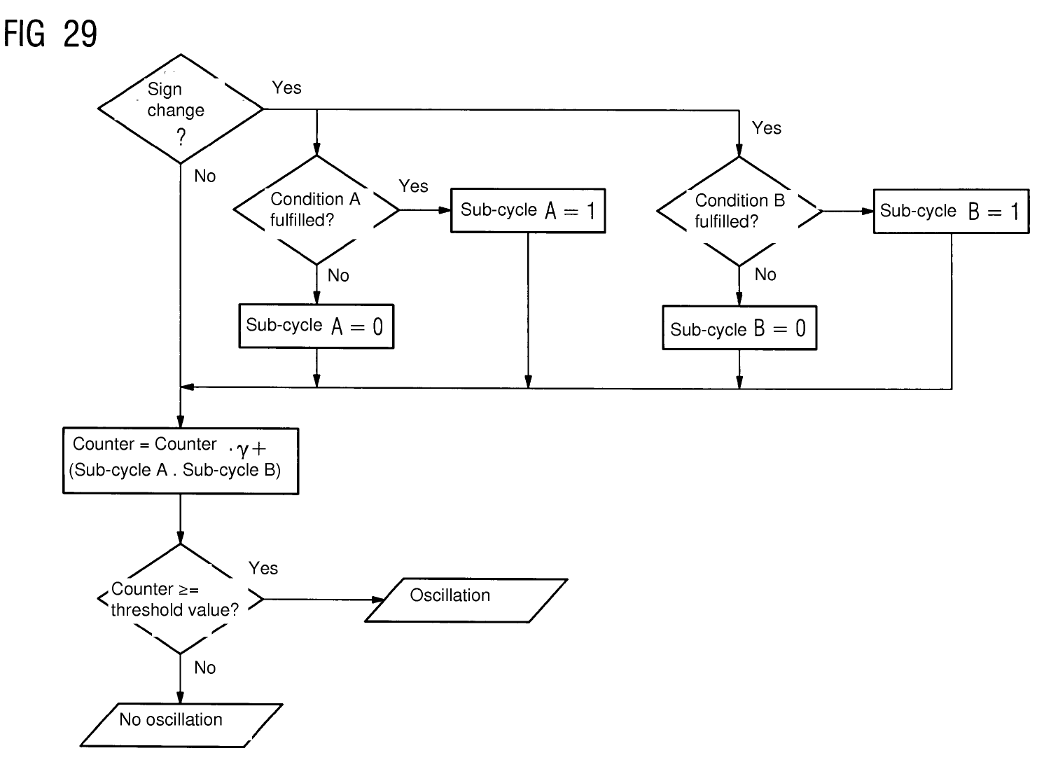

In FIG. 29 shows the algorithm for on-line detection as a flowchart. This algorithm is executed at each timestep.

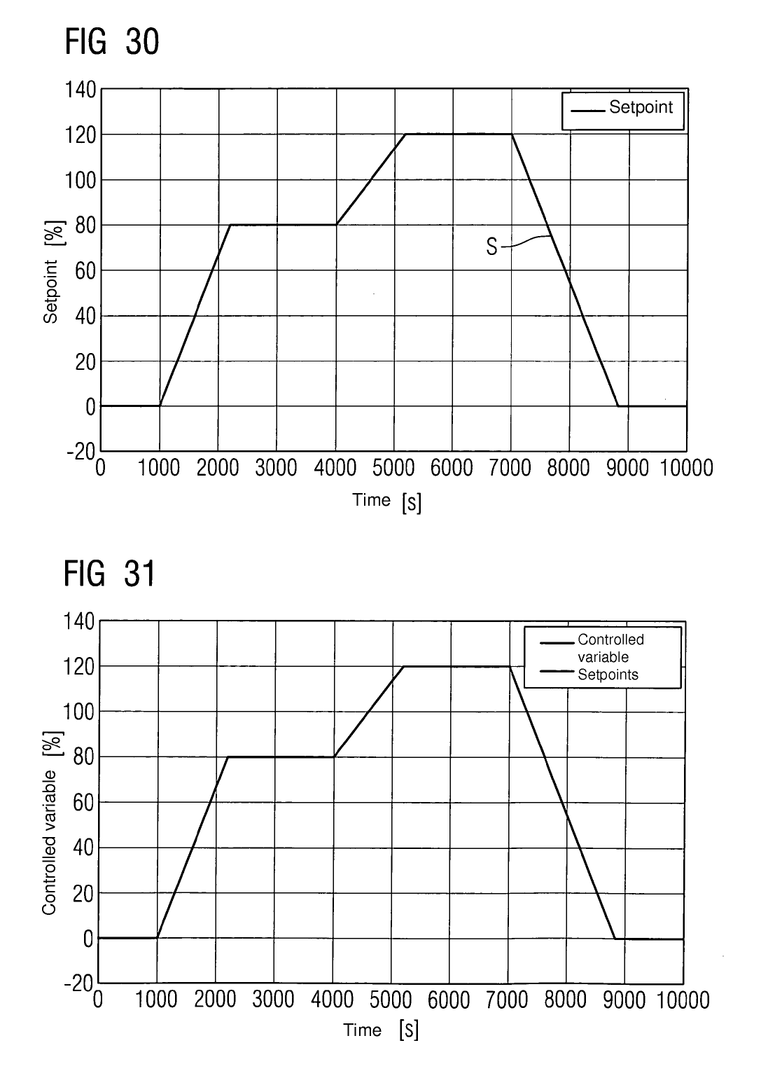

Testing of the control circuit quality monitoring will now be described. The simulated controlled system has a cumulative time constant of Tₛᵤₘ=100 s. Three ramps are defined as setpoint changes, see FIG. 30. The ramps have a rate of change of 4%/min, 2%/min and =4%/min.

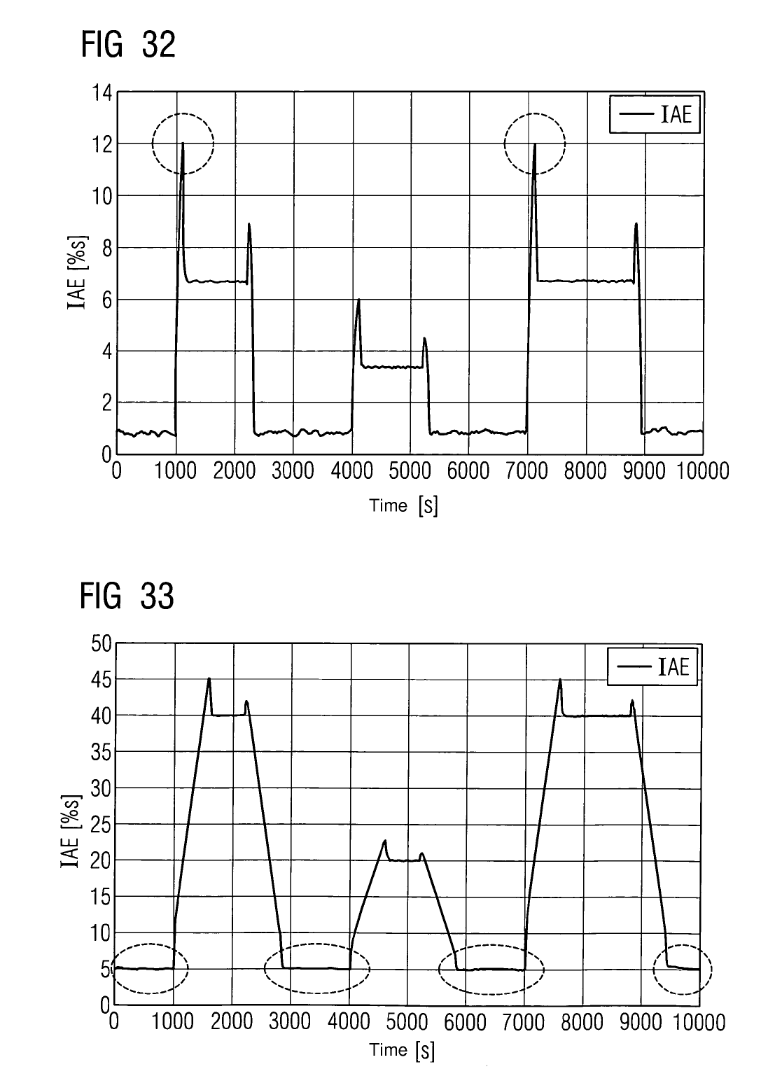

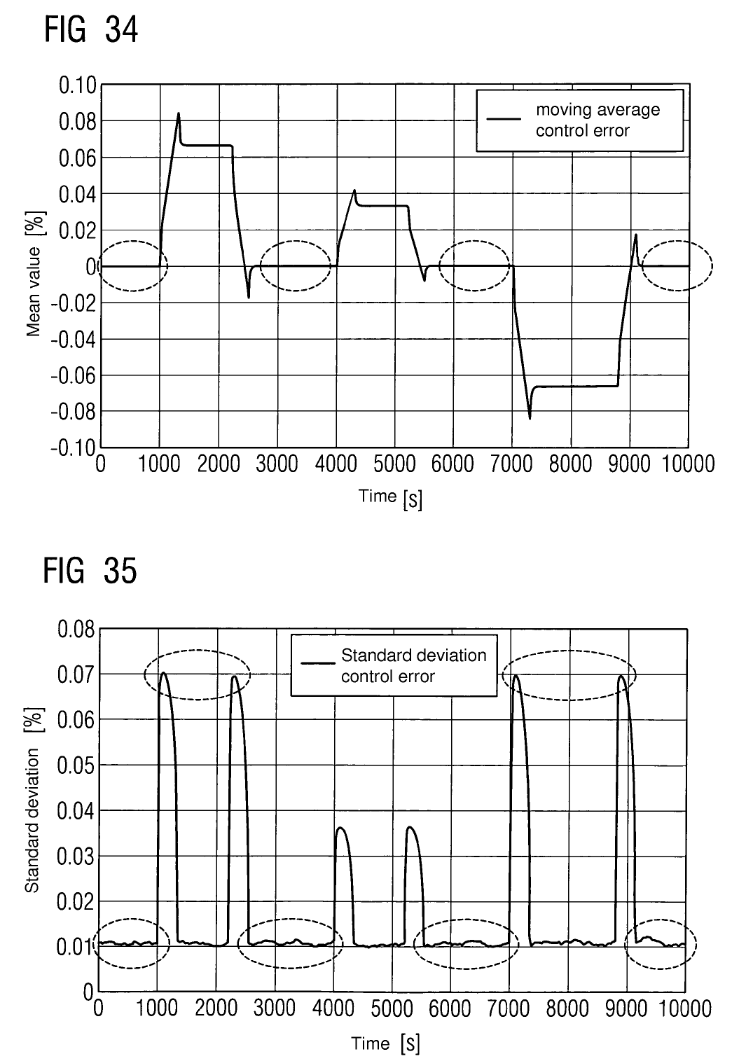

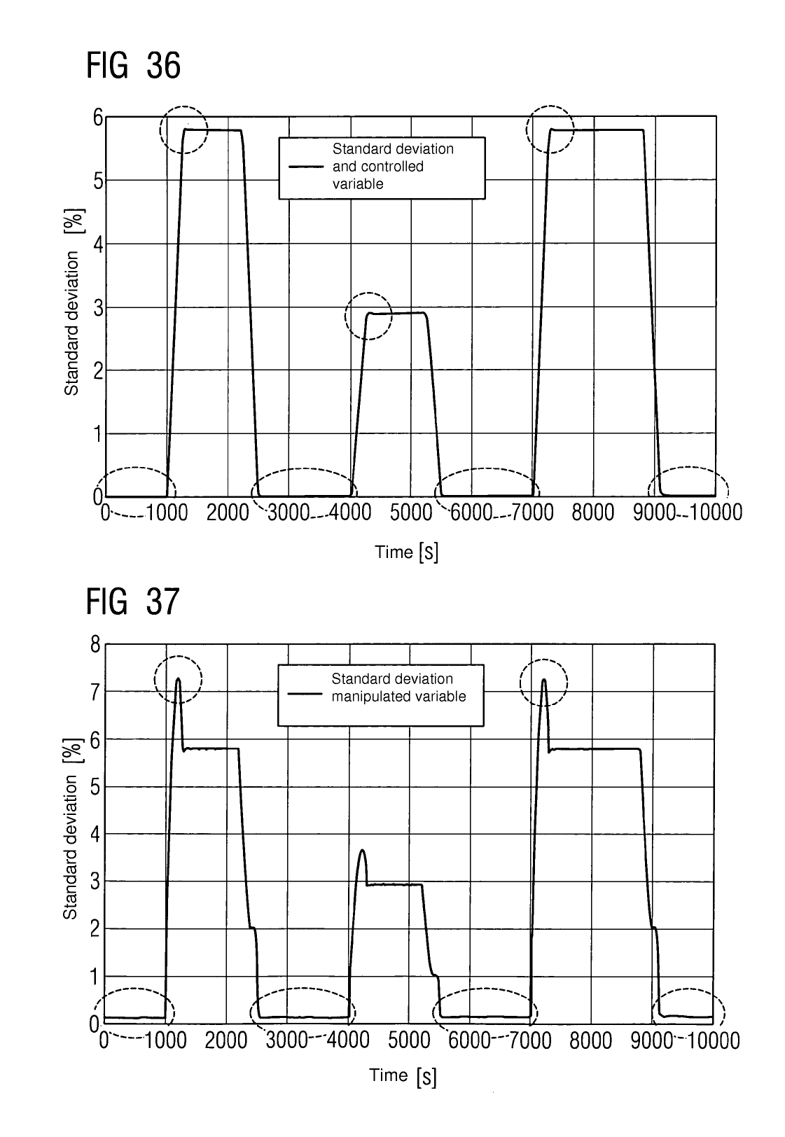

In the learning phase, characteristic quantities for the control quality reference are recorded. In addition to the setpoint changes, white noise with intensity 1 is applied to the system. For the previously defined setpoint response, see FIG. 31, the waveforms shown in FIGS. 32 to 37 are produced. For example, FIG. 32 shows the IAE response for dynamic processes in which the relevant curve maxima are marked, whereas FIG. 33 shows the IAE response for steady-state detection in which the relevant curve minima are marked. The IAE calculation differs in respect of the monitoring time (“IAE short” or “IAE long”).

The following reference values are produced:

| Criterion | Reference value |
|---|---|
| IAE short | 12 |
| IAE long | 5 |
| Moving average | 0 |
| Standard deviation control error | Min: 0.01; Max: 0.07 |
| Standard deviation controlled variable | Min: 0.01; Max: 5.85 |
| Standard deviation manipulated variable | Min: 0.1; Max: 7.3 |
| Wind-up | 0 |
| Oscillation index | 0 |

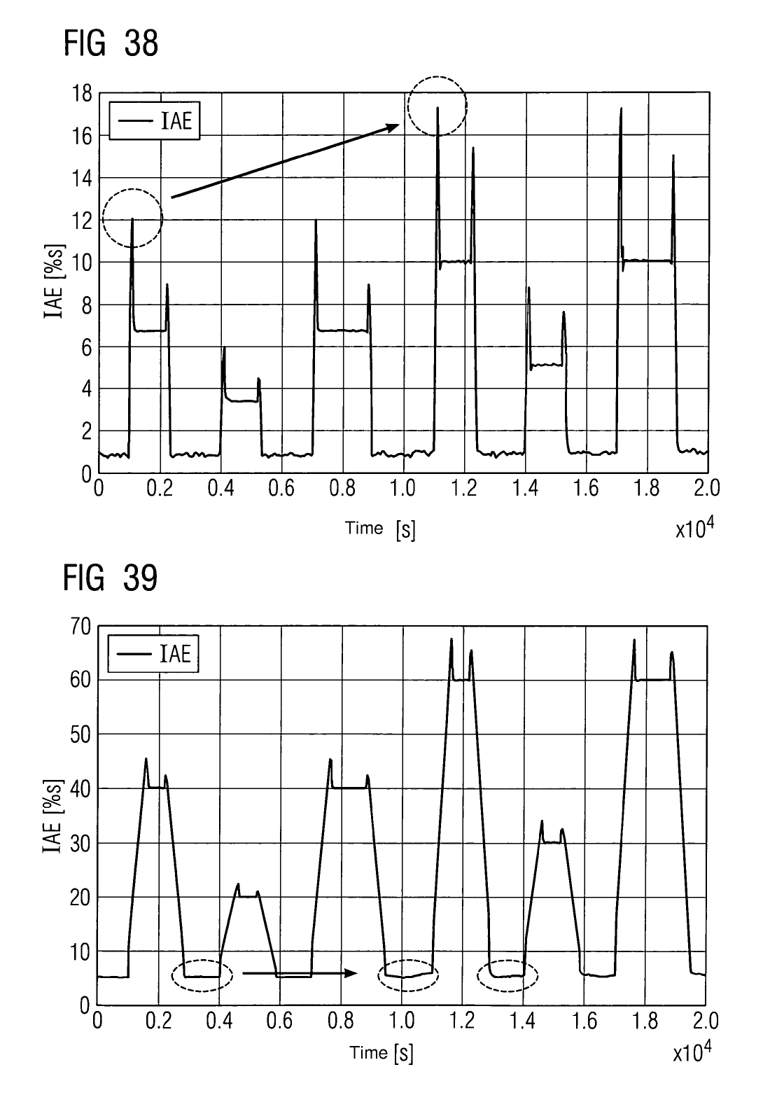

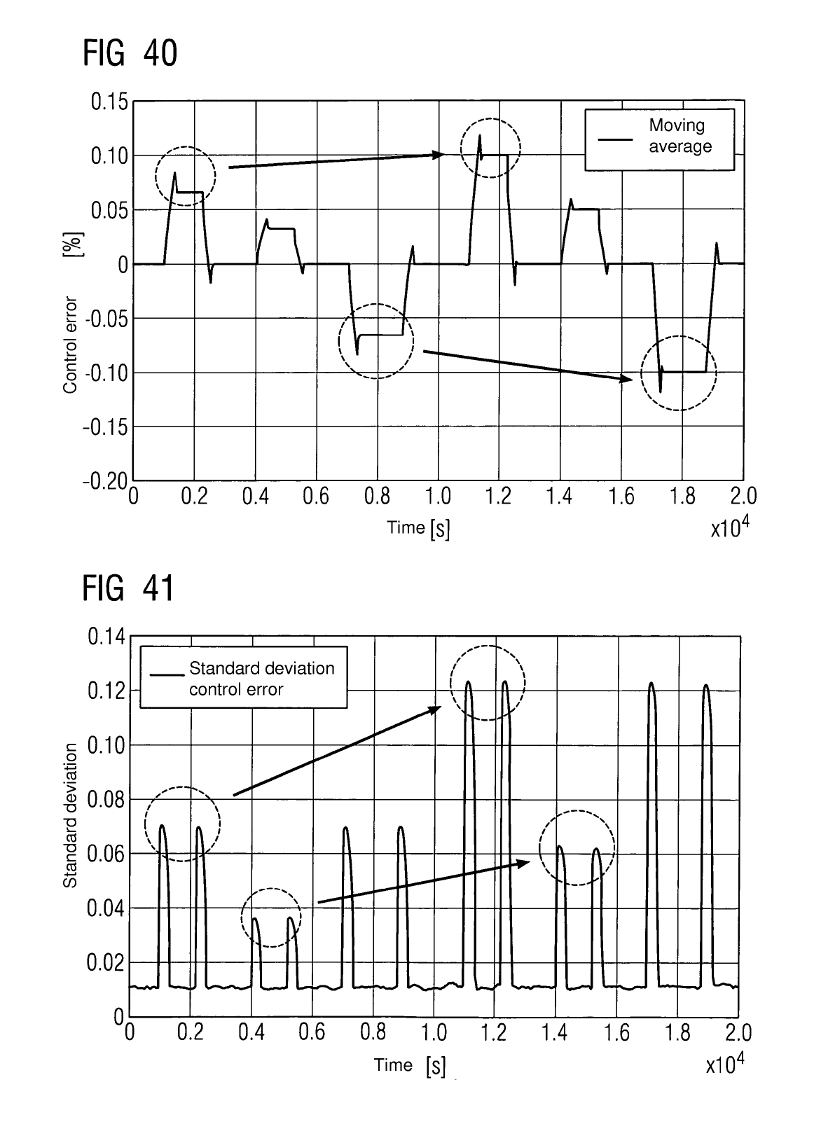

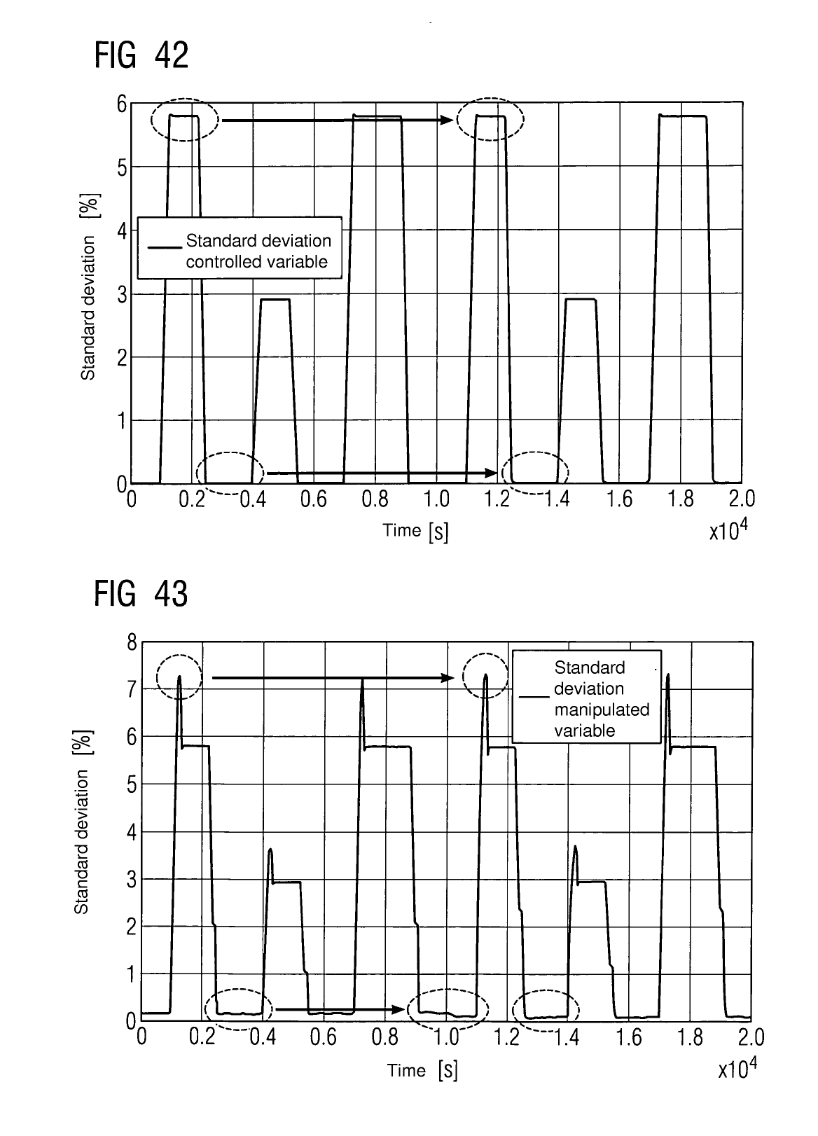

Next the behavior of the controlled system is simulated using an actuator which is more sluggish than in the learning phase, i.e. the actuator's time constant is greater than in the learning phase, T_{act}>T_{act,Ref}. For this case the waveforms as shown in FIGS. 38 to 43 are produced. Clearly visible are the positive changes in the minimum and maximum of the IAE response, i.e. a more sluggish control circuit is detected both under steady-state conditions and in the case of setpoint changes. The inertia is additionally manifested in a larger mean value of the control deviation after setpoint changes and in the larger standard deviation of the control error. The minimum of the standard deviation of the manipulated variable is reduced in the case a more sluggish actuator. The current values and changes are set out in the following table.

| Criterion | Current value | Change [%] |
|---|---|---|
| IAE short | 17.3 | 44 |
| IAE long | 6 | 20 |
| Moving average | 0 | 0 |
| Standard deviation control error | Min: 0.01; | 0 |
| | Max: 0.125 | 79 |
| Standard deviation controlled | Min: 0.01; | 0 |
| variable | Max: 5.85 | 0 |
| Standard deviation manipulated | Min: 0.05; | −50 |
| variable | Max: 7.35 | 0.07 |
| Wind-up | 0 | 0 |
| Oscillation index | 0 | 0 |

Detecting a deterioration in the control quality is critically dependent on the tolerance setting. The tolerance specifies the deviation in exceedance of which the control circuit quality monitoring system operates. The larger the tolerance, the larger the deviations from the reference values can be.

If the parameters are selected too large, a deterioration in control quality will not be detected in some circumstances. If they are too small, natural fluctuations will cause a “false” detection of control quality deterioration and the control circuit quality monitoring system will too often produce alarm indications.

The tolerance is preferably set such that no deviating control quality would have been found during the learning phase. This means that the maximum value of the characteristic quantity is within tolerance, this assuming that the occurrence of the maximum value of the characteristic quantity is still assessed as satisfactory.

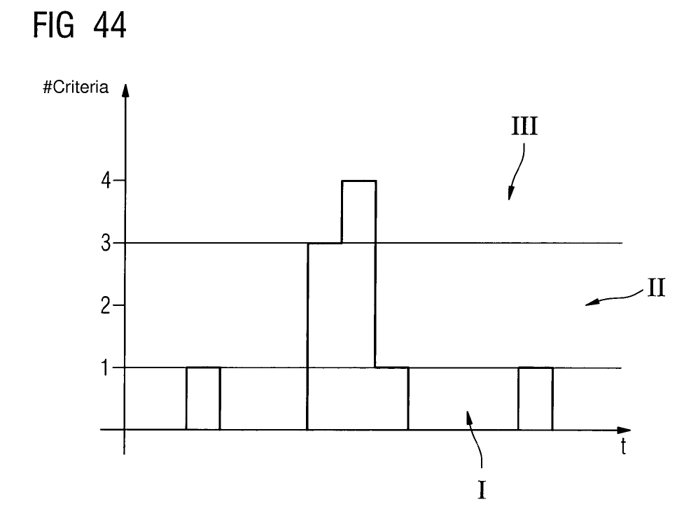

To output the results of the control circuit quality monitoring system, the characteristic quantities are preferably displayed. One possibility is to graphically represent the various plant sections and control circuits on a screen and to visualize the current control quality by assigning a color code to the individual objects represented. Another possibility is to display the number of characteristic quantities exceeding the tolerance limits, see FIG. 44. Said display is preferably subdivided into three ranges. A first range I will display a non-critical indication which is not necessarily associated with a deteriorated control quality, e.g. if only one characteristic quantity exceeds the specified tolerance value. A second range II of the display will indicate a deteriorated control quality that is tolerable, but must be investigated, e.g. having two or three deficient characteristic quantities. A third range III of the display will indicate a severely deteriorated control quality compared to the reference, e.g. having more than three deficient characteristic quantities. In the latter case, warnings are immediately issued in the instrumentation and control system.

If a plurality of subordinate controls systems are combined, e.g. a plurality of controlled coal pulverizers of a coal-fired power plant, criteria are added and the ranges adapted. In the event of reduced control quality, the relevant control circuit is quickly found. The apportionment of the ranges is performed during or after the learning phase in order to check the informative value.

The setting of the tolerance parameters and the breakdown of the ranges critically determines how the system will react to reduced control quality and inform the user. If the tolerances are selected too small and the range limits too low, the control circuit quality monitoring system will react too quickly. Conversely, i.e. with the tolerances too large and the range limits too high, no control quality deterioration will be indicated.

Self-evidently the display ranges can also be defined differently. The results of quality monitoring can likewise be displayed in some other way.

1-9. (canceled)

10. A method of monitoring quality of a control circuit in a power plant, comprising:
continuously assessing the quality of the control circuit by
determining characteristic quantities describing the quality by applying a plurality of testing methods suitable for describing dynamic properties of the control circuit to current operating data originating from the instrumentation and control equipment of the power plant; and
evaluating the characteristic quantities.

11. The method as claimed in claim 10, wherein a power plant operation is subdivided into load profiles and the quality is assessed separately for each of the load profiles such that the characteristic quantities describe the quality at constant load.

12. The method as claimed in claim 10, wherein a power plant operation is subdivided into load profiles and the quality is assessed separately for each of the load profiles such that the characteristic quantities describe the quality at load changes.

13. The method as claimed in claim 10, wherein a power plant operation is subdivided into load profiles and the quality is assessed separately for each of the load profiles such that the characteristic quantities describe the quality at constant load and load changes.

14. The method as claimed in claim 10, wherein the testing methods suitable for describing dynamic properties of the control circuit are selected from the group consisting of the following testing methods: determining the integral absolute control error (IAE), determining the moving average, determining the standard deviation, detecting the occurrence of wind-up, detecting oscillations, and a combination thereof.

15. The method as claimed in claim 10, wherein, in a learning phase, a reference control quality is determined which is used as a comparison value for assessing the control quality in a monitoring phase following the learning phase.

16. The method as claimed in claim 10, wherein, for evaluating the characteristic quantities, an exceedance of permissible deviations is determined and a deterioration of the controlled variable is output as the number of characteristic quantities including such an exceedance.

17. The method as claimed in claim 10, wherein the characteristic quantities are stored in an archive.

18. The method as claimed in claim 10, wherein the characteristic quantities are made available for a detailed analysis.

19. The method as claimed in claim 10, wherein the characteristic quantities are stored in an archive and are made available for a detailed analysis.

20. A system of monitoring quality of a control circuit in a power plant, comprising:
means for continuously assessing the quality of the control circuit including
means for determining characteristic quantities describing the quality by applying a plurality of testing methods suitable for describing dynamic properties of the control circuit to current operating data originating from the instrumentation and control equipment of the power plant; and
means for evaluating the characteristic quantities.

21. A computer readable medium storing a computer program for monitoring quality of a control circuit in a power plant, with computer program instructions for continuous assessment of the control quality by determining characteristic quantities describing the control quality by applying a plurality of testing methods suitable for describing dynamic properties of a control circuit to current operating data originating from the instrumentation and control equipment of the power plant and evaluating the characteristic quantities when the computer program is run on a computer.

22. The computer readable medium as claimed in claim 21, wherein a power plant operation is subdivided into load profiles and the quality is assessed separately for each of the load profiles such that the characteristic quantities describe the quality at constant load.

23. The computer readable medium as claimed in claim 21, wherein a power plant operation is subdivided into load profiles and the quality is assessed separately for each of the load profiles such that the characteristic quantities describe the quality at load changes.

24. The computer readable medium as claimed in claim 21, wherein a power plant operation is subdivided into load profiles and the quality is assessed separately for each of the load profiles such that the characteristic quantities describe the quality at constant load and load changes.

25. The computer readable medium as claimed in claim 21, wherein the testing methods suitable for describing dynamic properties of the control circuit are selected from the group consisting of the following testing methods: determining the integral absolute control error (IAE), determining the moving average, determining the standard deviation, detecting the occurrence of wind-up, detecting oscillations, and a combination thereof.

26. The computer readable medium as claimed in claim 21, wherein, in a learning phase, a reference control quality is determined which is used as a comparison value for assessing the control quality in a monitoring phase following the learning phase.

27. The computer readable medium as claimed in claim 21, wherein, for evaluating the characteristic quantities, an exceedance of permissible deviations is determined and a deterioration of the controlled variable is output as the number of characteristic quantities including such an exceedance.

28. The computer readable medium as claimed in claim 21, wherein the characteristic quantities are stored in an archive.

29. The computer readable medium as claimed in claim 21, wherein the characteristic quantities are made available for a detailed analysis.
